(19) United States
(12) Patent Application Publication
(10) Pub. No.: US 2026/0229417 A1
(43) Pub. Date: Aug. 6, 2026

(54) A POLYMER ELECTROLYTIC CAPACITOR COMPRISING A SOLUTION-PROCESSED N-TYPE CONDUCTING POLYMER

(71) Applicant: WESTRA MATERIALS AB, Norrköping (SE)

(72) Inventors: Qifan Li, Norrköping (SE); Jun-Da Huang, Norrköping (SE); Chi-Yuan Yang, Norrköping (SE); Simone Fabiano, Norrköping (SE); Marc-Antoine Stoeckel, Norrköping (SE)

(73) Assignee: WESTRA MATERIALS AB, Norrköping (SE)

(21) Appl. No.: 19/149,389

(22) PCT Filed: Feb. 10, 2023
(86) PCT No.: PCT/EP2023/053391

§ 371 Date: Jul. 18, 2025

(51) Int. Cl. H01G 9/028; H01G 9/00; H01G 9/04; H01G 9/042; H01G 9/045; H01G 9/052; H01G 9/08

(52) U.S. Cl. CPC H01G 9/028; H01G 9/0036; H01G 9/0425; H01G 9/045; H01G 9/08; H01G 2009/05; H01G 9/0525

(57) ABSTRACT

The present invention relates to a polymer electrolytic capacitor comprising an anode, a dielectric layer and a cathode, wherein said cathode comprises a solution-processed n-type conducting polymer.

### TECHNICAL FIELD

The present invention relates to a polymer electrolytic capacitor comprising a solution-processed n-type conducting polymer, and a method for manufacturing a water-based n-type conducting polymer for use in such a device.

### BACKGROUND OF THE INVENTION

Water-based conducting polymer inks have broad industrial applications, such as antistatic coatings, polymer capacitors, organic solar cells, displays (LCD/OLED), and printed electronics. PEDOT:PSS is a commercially available p-type (hole-transporting) water-based conducting polymer ink with a pristine electrical conductivity >1 S cm⁻¹, reaching values >4000 S cm⁻¹ after secondary doping or post-treating. However, water-based n-type (electron-transporting) conducting polymers are crucial when considering complementary components in semiconducting devices and circuitry.

The BBL: PEI ethanol-based inks reported in WO 2022/106017 and WO 2022/106018 are the first step towards environmentally friendly solvent n-type inks. However, there are several problems partially limiting their application. First of all, ethanol has strict requirements for fire prevention during production, transportation, storage, and usage. Further, the inks disclosed in the above-referenced applications are mainly limited to deposition methods such as spray-casting, spin-casting and the like due to the large particle size. As may be gleaned from the above-cited references, the highest electrical conductivity of BBL: PEI inks is below 10 S cm-1, which make them unsuitable for devices sensitive to sheet resistance.

Recently, Fei Huang et al. reported a solution-processed n-type conducting polymer poly(benzodifurandione) (PBFDO) with electrical conductivity over 2000 S/cm (Nature, 2022, s41586-022-05295-8).

Developing a water-based n-type CP ink with high conductivity, processability, and stability equivalent to PEDOT:PSS remains a challenging scientific and industrial endeavour with widespread impact in low-cost printed organic electronics.

A polymer electrolytic capacitor is an electrolytic capacitor (e-cap) with a solid conductive polymer electrolyte. There are four different types: polymer tantalum electrolytic capacitor (Polymer Ta-e-cap), polymer aluminium electrolytic capacitor (Polymer Al-e-cap), hybrid polymer capacitor (Hybrid polymer Al-e-cap), and Polymer niobium electrolytic capacitors.

Polymer Ta-e-caps are available in rectangular surface-mounted device (SMD) chip style. Polymer Al-e-caps and hybrid polymer Al-e-caps are available in rectangular surface-mounted device (SMD) chip style, in cylindrical SMDs (V-chips) style or as radial leaded versions (single-ended).

Polymer electrolytic capacitors are characterized by particularly low internal equivalent series resistances (ESR) and high ripple current ratings. Their electrical parameters have similar temperature dependence, reliability and service life compared to solid tantalum capacitors, but have a much better temperature dependence and a considerably longer service life than aluminium electrolytic capacitors with non-solid electrolytes. In general polymer e-caps have a higher leakage current rating than the other solid or non-solid electrolytic capacitors.

Polymer electrolytic capacitors are also available in a hybrid construction. The hybrid polymer aluminium electrolytic capacitors combine a solid polymer electrolyte with a liquid electrolyte. These types are characterized by low ESR values but have low leakage currents and are insensitive to transients, however they have a temperature-dependent service life similar to non-solid e-caps.

Polymer electrolytic capacitors are mainly used in power supplies of integrated electronic circuits as buffer, bypass and decoupling capacitors, especially in devices with flat or compact design. Thus they compete with MLCC capacitors, but offer higher capacitance values than MLCC, and they display no microphonic effect (such as class 2 and 3 ceramic capacitors).

The most important electrical property of an electrolyte in an electrolytic capacitor is its electrical conductivity. The electrolyte forms the counter electrode, of the e-cap, the cathode. The benefits provided by a solid polymer electrolyte are the significantly lower ESR of the capacitor and the low temperature dependence of the electrical parameters.

Currently available polymer electrolytes are made of precursors consisting of very small base materials that can penetrate even the smallest pores. The size of this precursors is the limiting factor in the size of the pores in the etched aluminium anode foils or of the size of tantalum powder. The rate of polymerization must be controlled for capacitor manufacturing. Too rapid polymerization does not lead to a complete anode coverage, while too slow polymerization increases production costs. Neither the precursors nor the polymer or its residues may attack the anodes oxide chemically or mechanically. The polymer electrolyte must have high stability over a wide temperature range over long times. Currently available polymer e-caps employ either polypyrrole (PPy) or polythiophene (PEDOT). However, capacitors comprising these polymers suffer from the disadvantage of poor thermal stability. The daily use temperature of supercapacitors used in areas such as autonomous driving can be above 170° C. The conductivity of conventional conducting polymers drops at such temperatures, even in encapsulation without air.

Therefore, there is a need for polymer electrolytic capacitors comprising a solution-processed, preferably water-based n-type CP ink with high conductivity, processability, and stability.

### SUMMARY OF THE INVENTION

Considering the above, the present invention aims to solve the problems of the prior art. To this end, the present invention relates to a polymer electrolytic capacitor comprising an anode, a dielectric layer and a cathode, wherein said cathode comprises a solution-processed n-type conducting polymer.

The anode may be tantalum (Ta) in the form of a high purity sintered tantalum powder as an anode with tantalum pentoxide (Ta₂O₅) as a dielectric.

Alternatively, the anode may be aluminium (Al) in the form of a high purity and electrochemically etched (roughened) aluminium foil with aluminium oxide (Al₂O₃) as the dielectric.

The solution-processed n-type conducting polymer may be poly(benzodifurandione) (PBFDO).

The polymer electrolytic capacitor may be in the form of a rectangular SMD chip, usually moulded with a plastic case, available with sintered tantalum anode or with stacked aluminium anode foils.

Alternatively, the polymer electrolytic capacitor may be in the form of a cylinder.

The polymer electrolytic capacitor may be encapsulated by e.g. a resin. Encapsulation prevents air contact and thus improved stability of the capacitor.

The solution-processed n-type conducting polymer used in the polymer electrolytic capacitor according to the present invention may be manufactured from an ink comprising the solution-processed n-type conducting polymer and a solvent system. The solvent system may comprise a polar aprotic solvent and/or a polar protic solvent.

In particular, the polar aprotic solvent may be selected from DMF, DMSO, and combinations thereof. The polar protic solvent may be selected from water, ethanol, propanol, butanol and combinations thereof.

The ink may be applied to the polymer electrolytic capacitor by means of dip-coating.

It must be mentioned that the polymer electrolytic capacitor according to the present invention shows a remarkable thermal stability of up to 200° C.

In a particular embodiment, the solution-processed n-type conducting polymer for use in the polymer electrolytic capacitor may be manufactured by a method comprising the steps of:
a) adding a monomer to a solvent system comprising water in the presence of a catalyst, thus providing a reaction solution;
b) allowing said monomer to polymerize in said reaction solution thus obtaining an n-type conducting polymer solution;
c) post-treating said n-type conducting polymer solution thus obtaining a water-soluble n-type conducting polymer.

The monomer has the central symmetrical benzene ring as the skeleton, active hydrogen and at least one electron-withdrawing group at the benzylic position. The electron-withdrawing groups may be carbonyl, carboxyl, amide, alkoxy acyl or the like.

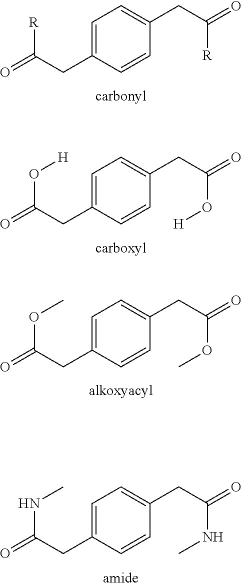

Further, the monomer may be in the form of a heterocyclic moiety having a central symmetrical benzene ring fused with at least one, preferably at least two rings, preferably five-membered rings. The monomer further comprises an active hydrogen and at least one electron-withdrawing group at the benzylic position. In particular, the monomer may be 3,7-dihydrobenzo[1,2-b: 4,5-b′]difuran-2,6-dione (HBFDO), 5,7-dihydropyrrolo[2,3-f]indole-2,6 (1H,3H)-dione, or 3,7-dihydrobenzo[1,2-b: 4,5-b′]dithiophene-2,6-dione.

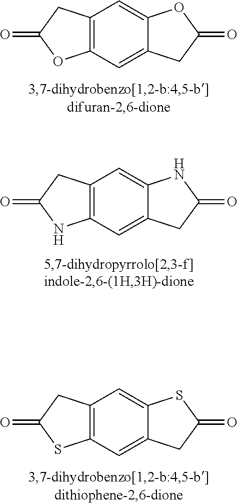 [SMILES: O=C1Cc2cc3c(cc2O1)CC(=O)O3 ; O=C1Cc2cc3c(cc2N1)CC(=O)N3 ; O=C1Cc2cc3c(cc2S1)CC(=O)S3]

In particular, the monomer may be 3,7-dihydrobenzo[1,2-b: 4,5-b]difuran-2,6-dione (HBFDO). In such an embodiment, the n-type conducting polymer is poly(benzodifurandione) (PBFDO). The general overview of the method of the present invention may be summarized as follows:

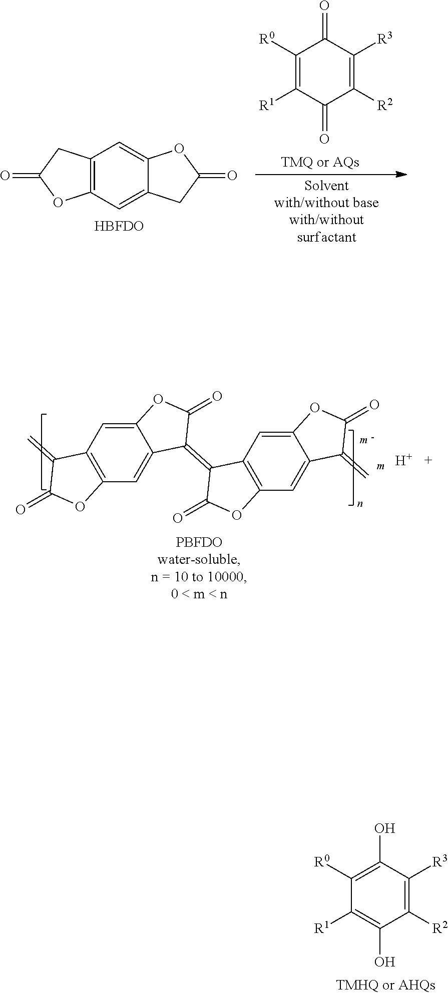

wherein TMQ or AQ is the catalyst, as depicted below.

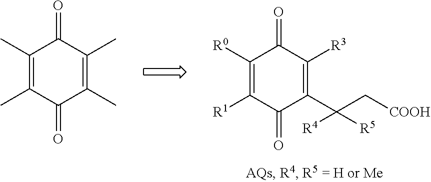

According to the first embodiment, the solvent system consists of water. In other words, the solvent system comprises substantially only water, e.g. at least 99 vol % water. Such an embodiment offers the advantage of a cost-efficient and environmentally friendly manufacturing method.

In an embodiment wherein the solvent system consists of water, the method further comprises a step of:

a′) adding a base to the reaction solution.

Step a) may occur during or immediately after step a). In other words, the base may be added to the reaction solution together with the monomer and the catalyst, or immediately after the addition of the monomer and the catalyst.

Additionally, the method may further comprise a step of:

a″) adding a surfactant to the reaction solution.

Step a′) may occur during or immediately after step a). In other words, the surfactant may be added to the reaction solution together with the monomer and the catalyst, or immediately after the addition of the monomer and the catalyst. Further, step a″) may occur immediately before, immediately after, or simultaneously with step a).

As may be understood from above, the surfactant is not essential for the method according to the first embodiment. However, the surfactant must be added if the polymer is intended to be used for spin-casting.

According to the first embodiment, the catalyst may be an alkyl- and carboxyl-substituted benzoquinone (AQ). Such a catalyst may be selected from the group consisting of 3-(2,4,5-trimethyl-3,6-dioxocyclohexa-1,4-dien-1-yl) propanoic acid (AMMMQ, R⁰=R¹=R³=Me), 3,3′-(4,5-dimethyl-3,6-dioxocyclohexa-1,4-diene-1,2-diyl)dipropionic acid (AAMMQ, R⁰=R¹=Me, R³=—CH₂R⁴R⁵COOH, R⁴, R⁵=H or Me), 3,3′-(2,5-dimethyl-3,6-dioxocyclohexa-1,4-diene-1,4-diyl)dipropionic acid (AMAMQ, R¹=R³=Me, R⁰=—CH₂R⁴R⁵COOH, R⁴, R⁵=H or Me) and combinations thereof.

The catalysts can be easily isolated, recovered, and recycled to further polymerize PBFDO, as shown in the scheme below.

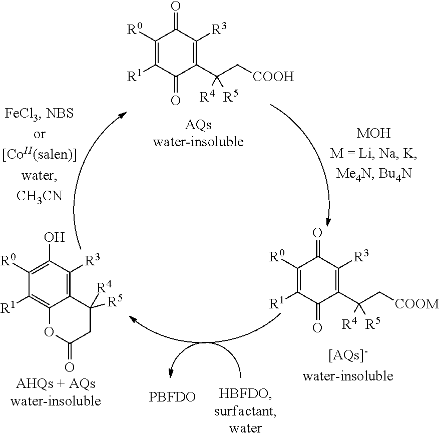

AQs can be synthesized by Michael addition followed by oxidation with N-bromosuccinimide (NBS), as is described in greater detail below. AQs are highly crystalline water-insoluble organic acids. However, when they are neutralized with strong bases, AQs will be converted into highly water-soluble [AQs]⁻. When the solvent system consists of water, [AQs]⁻ can catalyse the polymerization of water-insoluble HBFDO monomer into water-soluble PBFDO in presence of a surfactant. It is remarkable that after the polymerization, the aqueous solution becomes strongly acidic, and the [AQs]⁻ will be converted into water-insoluble AHQs and AQs, which can be separated from the PBFDO ink by simple suction filtration. The mix of AHQs and AQs can be converted into pure AQs by mild oxidation. Consequently, AQs are readily recyclable, thus offering the advantage of cost-efficiency and low environmental impact.

According to the first embodiment of the present invention, the base may be MOH, wherein M is selected from Lit, Na⁺, K⁺, Me₄N⁺, Bu₄N⁺ or combination thereof.

The surfactant may be selected from polyethylene glycol (PEG), polyvinylpyrrolidone (PVP), polyvinyl alcohol (PVA), sodium polystyrene sulfonate (PSSNa), poly(styrene sulfonate) acid (PSSH), sodium dodecylbenzenesulfonate (DBSNa), polyquaternium-4 (PQ-4), polyquaternium-10 (PQ-10), polydiallyldimethylammonium chloride (PDADMAC), polydiallyldiethylammonium chloride (PDADEAC), TWEEN® 20, TWEEN® 80, κ-Carrageenan, PEG-PPG-PEG, Polyoxyethylene (10) tridecyl ether, Triton™ X-100 or combination thereof.

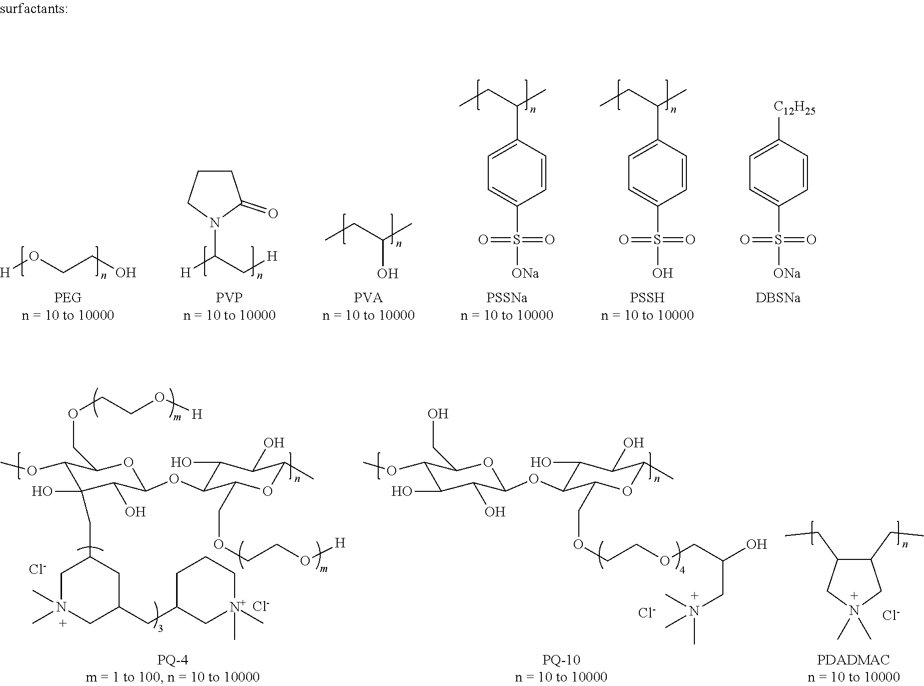

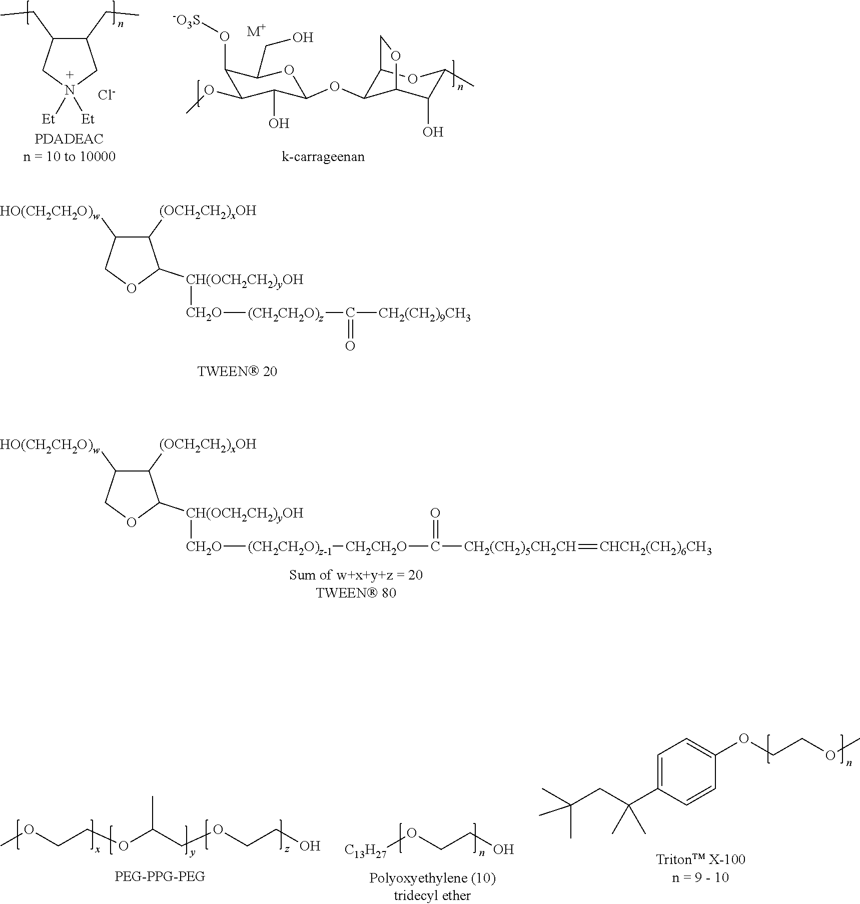

PBFDO dissolved in DMSO and obtained by using the polymerization method reported by Huang et al. precipitates after adding water to the DMSO solution. In other words, PBFDO polymerized in DMSO cannot be dissolved in water, even in the presence of surfactants such as polyethylene glycol (PEG). The inventors surprisingly found that performing the initial polymerization in water in the presence of AQs and a base promotes the formation of water-soluble PBFDO micelles, that are further stabilized by addition of a surfactant.

According to the second embodiment of the present invention, the solvent system may comprise a polar aprotic solvent. In such an embodiment, the method further comprises the step of:

d) solvent exchanging such that the polar aprotic solvent is removed.

The polar aprotic solvent may be dimethyl sulfoxide (DMSO), dimethyl formamide (DMF), dimethyl acetamide (DMA) or a combination thereof. The ratio between water and the polar aprotic solvent may be from 5:95 to 95:5, preferably from 40:60 to 60:40.

According to the second embodiment of the present invention, i.e. wherein the solvent system comprises a polar aprotic solvent, the catalyst may be a quinone oxidant selected from tetramethyl benzoquinone (TMQ), alkyl- and carboxyl-substituted benzoquinones (AQs), or combination thereof.

The inventors have surprisingly found that performing the polymerization reaction in a solvent system comprising water and a polar aprotic solvent promotes the formation of water-soluble PBFDO micelles, that may be further stabilized by addition of a surfactant, e.g. as disclosed above. It should be noted that according to the second embodiment of the present invention, the surfactant is not essential. If used, the surfactant may be added during said step d).

Even after the polar aprotic solvent is completely removed, the PBFDO micelles can still dissolve in water.

The polymerization step, i.e. step b) may occur at a temperature from 20° C. to 150° C. In particular, [AQs]- showed much stronger catalytic activity compared to TMQ. According to the second embodiment of the present invention, i.e. wherein the solvent system comprises a polar aprotic solvent, [AQs]- can catalyse the polymerization of HBFDO into PBFDO at room temperature, which is a great advantage in terms of cost-efficiency.

As mentioned above, the method of the present invention may further comprise a step of:

c′) removing the catalyst by filtration, oxidation and recycling the catalyst.

Finally, the method of the present invention may comprise additional steps, e.g. post-processing and purification steps. Such steps may also be performed in water.

The present invention further relates to a water-soluble n-type conducting polymer obtained by the method described above. The polymer may be in the form of micelles having a diameter lower than 200 nm. The particle size may easily be verified by filtration of the polymer solution through a 20 μm filter, whereupon it may be observed that the solution remains coloured, thus indicating that the polymer micelles pass through the filter.

Moreover, the present invention relates to a water-based ink comprising the water-soluble n-type conducting polymer as mentioned above.

The n-type conducting ink of the present invention may thus be spin-coated or drop-cast in air and ambient temperature, forming the film having thicknesses from 1 nm to 1 cm, more preferably from 10 nm to 10 μm. Such a film may exhibit electrical conductivity in the order of 5 S/cm.

### BRIEF DESCRIPTION OF THE DRAWINGS

Embodiments of the invention will now be described by way of example with reference to the accompanying drawings, of which:

FIG. 1 shows schematic view of the different embodiments of the polymer electrolytic capacitor according to the present invention;

FIGS. 2, 3a and 3b show perspective view and cross-section of the polymer electrolytic capacitors depicted in FIG. 1;

FIG. 4 depicts conductivity change of the polymer electrode during annealing at 200° C. in nitrogen;

FIG. 5 illustrates conductivity change of the polymer electrode during annealing at 200° C. in air, wherein the capacitor comprises resin encapsulation;

FIG. 6 shows conductivity change of the polymer electrode during annealing at 300° C. in nitrogen;

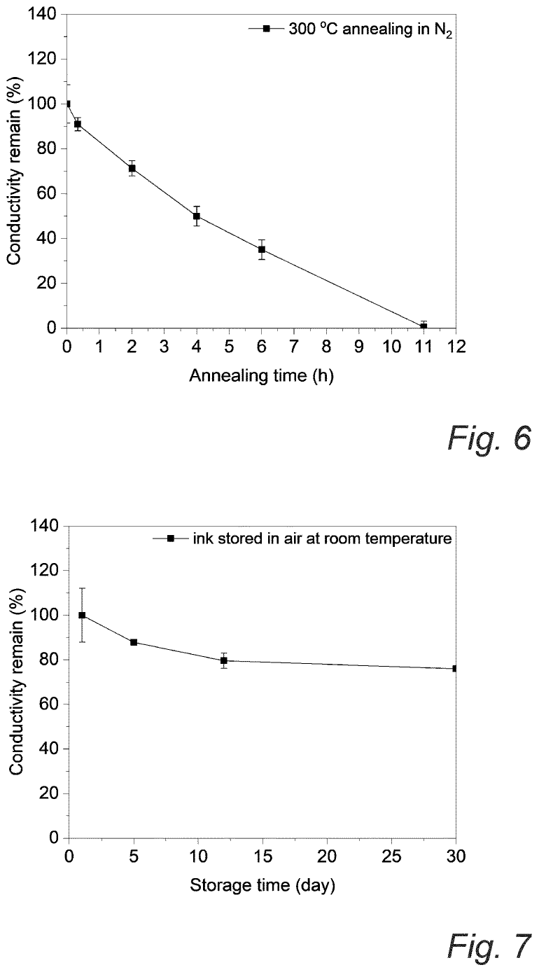

FIG. 7 depicts conductivity change of the polymer ink that is stored in air;

FIGS. 8-9 depict the steps of the method for manufacturing a water-based n-type conducting polymer for use in the polymer electrolytic capacitor according to the present invention.

### DETAILED DESCRIPTION OF THE INVENTION

As mentioned above, the present invention provides a polymer electrolytic capacitor comprising an anode, a dielectric layer and a cathode, wherein said cathode comprises a solution-processed n-type conducting polymer.

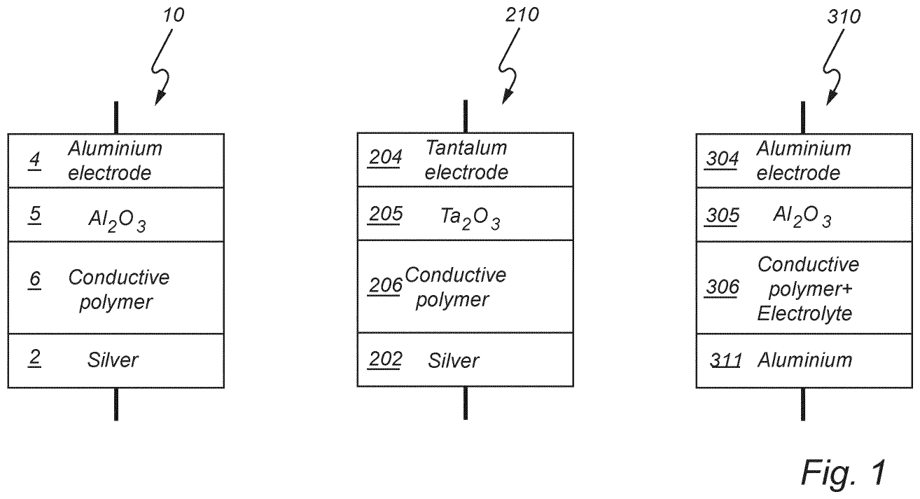

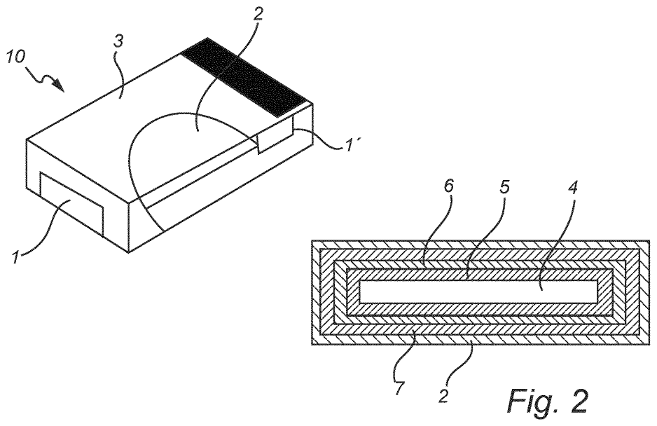

In the embodiments shown in FIG. 1, different types of polymer electrolytic capacitors are shown from left to right: polymer aluminium electrolytic capacitor (Polymer Al-e-cap), polymer tantalum electrolytic capacitor (Polymer Ta-e-cap), and hybrid polymer capacitor (Hybrid polymer Al-e-cap). Further, FIG. 2a shows perspective and cross sectional view of the polymer Al-e-cap. Analogously, FIG. 3a shows perspective and cross sectional view of the Polymer Ta-e-cap, FIG. 3b shows perspective and cross sectional view of the Hybrid polymer Al-e-cap.

As may be seen in FIG. 2, a polymer electrolytic capacitor 10 is depicted. The capacitor 10 comprises two terminals 1 and 1′, a silver paste layer 2 and an encapsulation layer 3 in the form of moulded resin. In the vertical cross-sectional view, aluminium foil 4 acts as anode, the aluminium oxide layer 5 acts as the dielectric, and the polymer layer 6 comprising the solution-processed n-type conducting polymer acts as cathode.

FIG. 3a depicts yet another embodiment of a rectangular capacitor 210 having tantalum anode 204, a tantalum pentoxide dielectric 205, a cathode layer 206 comprising solution-processed n-type conducting polymer, and a silver paste layer 202. As may be seen in FIG. 3a, the capacitor 210 comprises an encapsulation layer 203 in the form of moulded resin.

Finally, FIG. 3b illustrates a polymer electrolytic capacitor 310 having a cylindric shape and comprising an aluminium anode 304, an aluminium oxide dielectric 305, a separation sheet 312 and a hybrid cathode 306 comprising solution-processed n-type conducting polymer and an electrolyte and impregnating the separation sheet 312.

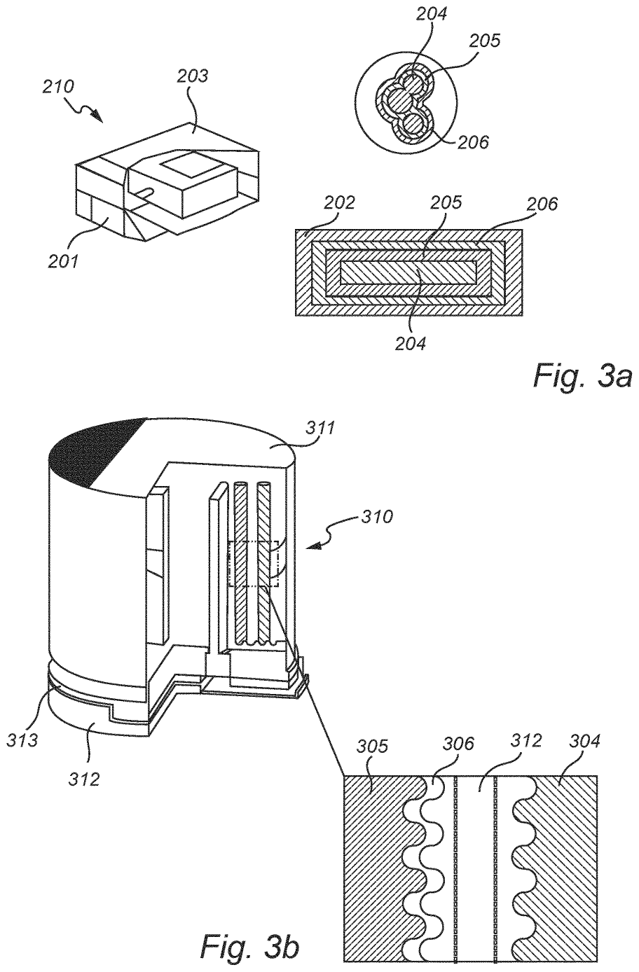

FIG. 4 depicts conductivity change of the polymer electrode during annealing at 200° C. in nitrogen. As may be seen, the capacitor of the present invention shows excellent thermal stability with almost unchanged conductivity even after 8 h.

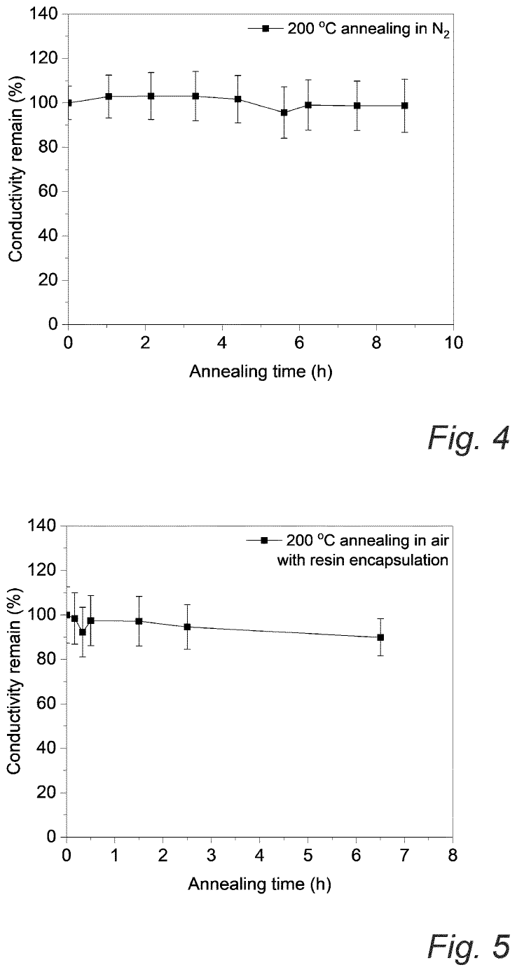

The capacitor comprising resin encapsulation may be annealed in air with good results. As may be seen in FIG. 5, conductivity dropped only insignificantly during annealing at 200° C. in air after 6 h.

When the annealing temperature was elevated 300° C., thermal stability was compromised, and conductivity dropped significantly already after 2 h in nitrogen atmosphere.

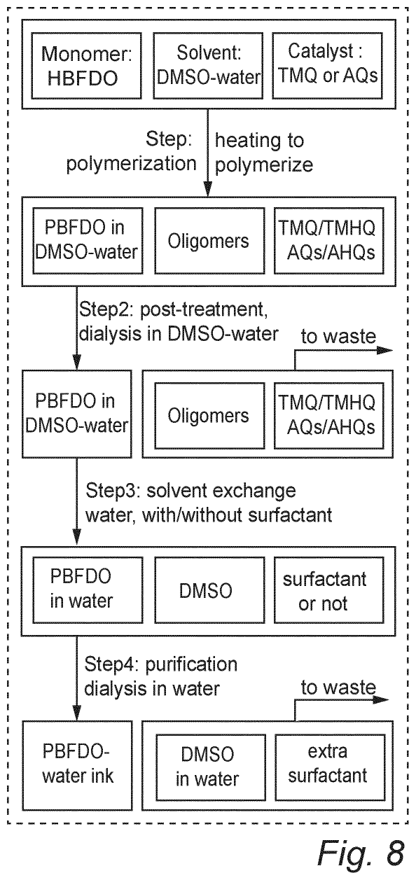

The ink comprising solution-processed n-type conducting polymer used in the polymer electrolytic capacitor of the present invention showed excellent storage stability, as may be seen in FIG. 7.

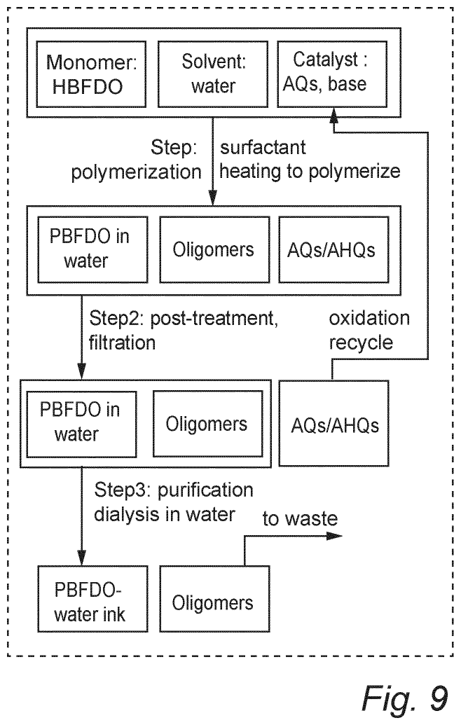

As shown in FIGS. 8 and 9, the water-based n-type conducting polymer for use in the polymer electrolytic capacitor may be manufactured by a method comprising the steps of:
a) adding a monomer to a solvent system comprising water in the presence of a catalyst, thus providing a reaction solution;
b) allowing said monomer to polymerize in said reaction solution thus obtaining an n-type conducting polymer solution;
c) post-treating said n-type conducting polymer solution thus obtaining a water-soluble n-type conducting polymer.

The monomer is 3,7-dihydrobenzo[1,2-b: 4,5-b]difuran-2,6-dione (HBFDO). In such an embodiment, the n-type conducting polymer is poly(benzodifurandione) (PBFDO). The general overview of the method of the present invention may be summarized as follows:

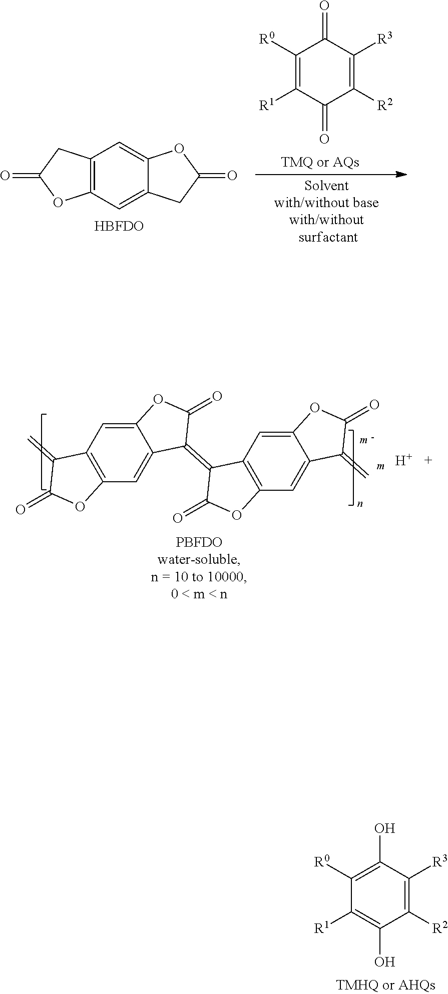

wherein TMQ or AQ is the catalyst, as depicted below.

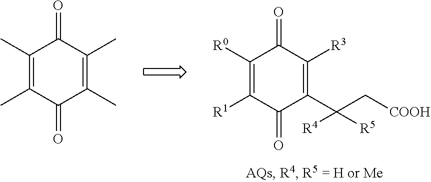

According to the first embodiment shown in FIG. 8, the solvent system consists of water. In other words, the solvent system comprises substantially only water, e.g. at least 99 vol % water. Such an embodiment offers the advantage of a cost-efficient and environmentally friendly manufacturing method.

In an embodiment wherein the solvent system consists of water, the method further comprises a step of:

a′) adding a base to the reaction solution.

Step a′) may occur during or immediately after step a). In other words, the base may be added to the reaction solution together with the monomer and the catalyst, or immediately after the addition of the monomer and the catalyst.

Additionally, the method shown in FIG. 8 further comprises a step of:

a″) adding a surfactant to the reaction solution.

Step a′) may occur during or immediately after step a). In other words, the surfactant may be added to the reaction solution together with the monomer and the catalyst, or immediately after the addition of the monomer and the catalyst. Further, step a″) may occur immediately before, immediately after, or simultaneously with step a).

As may be understood from above, the surfactant is not essential for the method according to the first embodiment. However, the surfactant must be added if the polymer is intended to be used for spin-casting.

According to the first embodiment, the catalyst may be an alkyl- and carboxyl-substituted benzoquinone (AQ). Such a catalyst may be selected from the group consisting of 3-(2,4,5-trimethyl-3,6-dioxocyclohexa-1,4-dien-1-yl) propanoic acid (AMMMQ, R⁰=R¹=R³=Me), 3,3′-(4,5-dimethyl-3,6-dioxocyclohexa-1,4-diene-1,2-diyl)dipropionic acid (AAMMQ, R⁰=R¹=Me, R³=—CH₂R⁴R⁵COOH, R⁴, R⁵=H or Me), 3,3′-(2,5-dimethyl-3,6-dioxocyclohexa-1,4-diene-1,4-diyl)dipropionic acid (AMAMQ, R¹=R³=Me, R⁰=—CH₂R⁴R⁵COOH, R⁴, R⁵=H or Me) and combinations thereof.

According to the first embodiment of the present invention, the base may be MOH, wherein M is selected from Lit, Na⁺, K⁺, Me₄N⁺, Bu₄N⁺ or combination thereof.

The surfactant may be selected from polyethylene glycol (PEG), polyvinylpyrrolidone (PVP), polyvinyl alcohol (PVA), sodium polystyrene sulfonate (PSSNa), poly(styrene sulfonate) acid (PSSH), sodium dodecylbenzenesulfonate (DBSNa), polyquaternium-4 (PQ-4), polyquaternium-10 (PQ-10), polydiallyldimethylammonium chloride (PDADMAC), polydiallyldiethylammonium chloride (PDADEAC), TWEEN® 20, TWEEN® 80, K-Carrageenan, PEG-PPG-PEG, Polyoxyethylene (10) tridecyl ether, Triton™ X-100 or combination thereof.

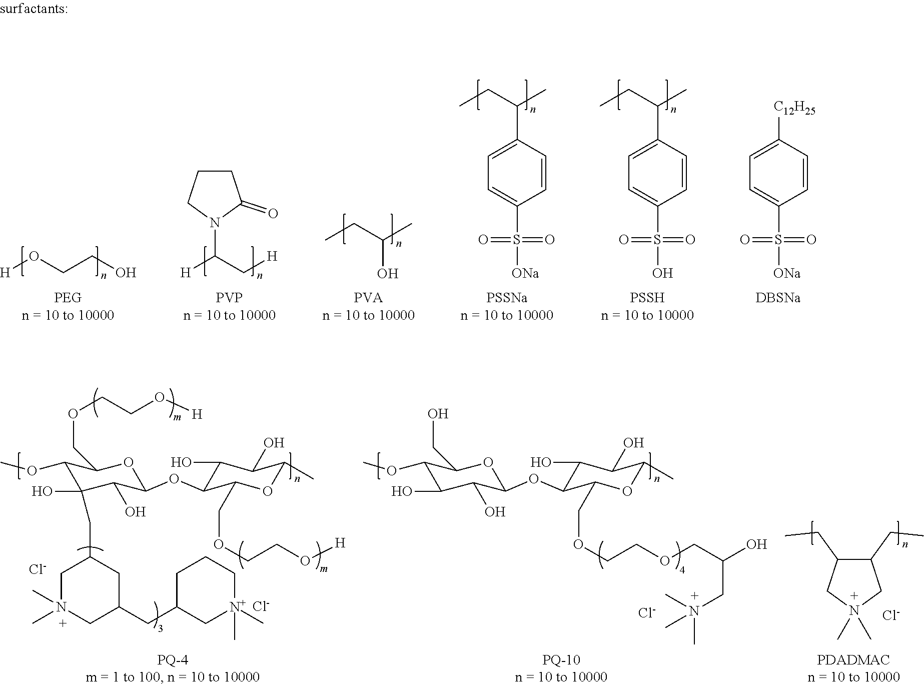

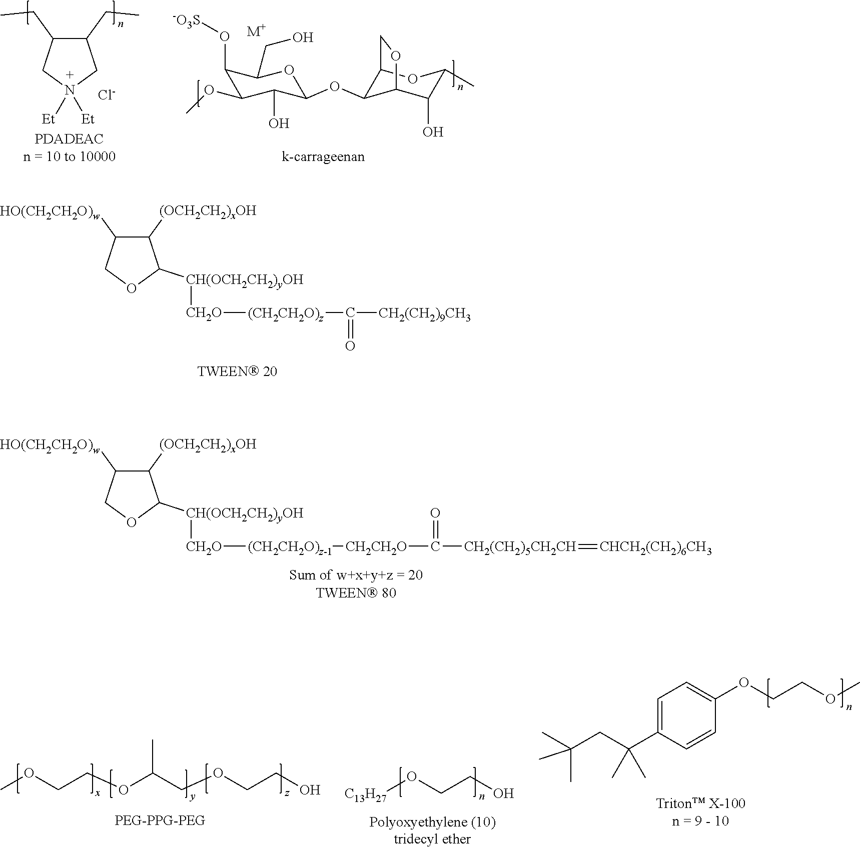

PBFDO dissolved in DMSO and obtained by using the polymerization method reported by Huang et al. precipitates after adding water to the DMSO solution. In other words, PBFDO polymerized in DMSO cannot be dissolved in water, even in the presence of surfactants such as polyethylene glycol (PEG). The inventors surprisingly found that performing the initial polymerization in water in the presence of AQs and a base promotes the formation of water-soluble PBFDO micelles, that are further stabilized by addition of a surfactant.

According to the second embodiment of the present invention shown in FIG. 7, the solvent system may comprise a polar aprotic solvent, e.g. DMSO. In such an embodiment, the method further comprises the step of:

d) solvent exchanging such that the polar aprotic solvent is removed.

The ratio between water and the polar aprotic solvent may be from 5:95 to 95:5, preferably from 40:60 to 60:40.

According to the second embodiment of the present invention, i.e. wherein the solvent system comprises a polar aprotic solvent, the catalyst may be a quinone oxidant selected from tetramethyl benzoquinone (TMQ), alkyl- and carboxyl-substituted benzoquinones (AQs), or combination thereof.

The inventors have surprisingly found that performing the polymerization reaction in a solvent system comprising water and a polar aprotic solvent promotes the formation of water-soluble PBFDO micelles, that may be further stabilized by addition of a surfactant, e.g. as disclosed above. It should be noted that according to the second embodiment of the present invention, the surfactant is not essential. If used, the surfactant may be added during said step d).

Even after the polar aprotic solvent is completely removed, the PBFDO micelles can still dissolve in water.

The polymerization step, i.e. step b) may occur at a temperature from 20° C. to 150° C. In particular, [AQs]- showed much stronger catalytic activity compared to TMQ. According to the second embodiment of the present invention, i.e. wherein the solvent system comprises a polar aprotic solvent, [AQs]- can catalyse the polymerization of HBFDO into PBFDO at room temperature, which is a great advantage in terms of cost-efficiency.

As mentioned above, the method of the present invention may further comprise a step of:

c′) removing the catalyst by filtration, oxidation and recycling the catalyst.

Finally, the method of the present invention may comprise additional steps, e.g. post-processing and purification steps. Such steps may also be performed in water.

According to the first embodiment, the catalyst may be an alkyl- and carboxyl-substituted benzoquinone (AQ). Such a catalyst may be selected from the group consisting of 3-(2,4,5-trimethyl-3,6-dioxocyclohexa-1,4-dien-1-yl) propanoic acid (AMMMQ, R⁰=R¹=R³=Me), 3,3′-(4,5-dimethyl-3,6-dioxocyclohexa-1,4-diene-1,2-diyl)dipropionic acid (AAMMQ, R⁰=R¹=Me, R³=—CH₂R⁴R⁵COOH, R⁴, R⁵=H or Me), 3,3′-(2,5-dimethyl-3,6-dioxocyclohexa-1,4-diene-1,4-diyl)dipropionic acid (AMAMQ, R¹=R³=Me, R⁰=—CH₂R⁴R⁵COOH, R⁴, R⁵=H or Me) and combinations thereof.

According to a particular embodiment of the present invention, the catalyst may be synthesized as follows. Methane sulfonic acid (10 mL) was heated to 70° C. in an oil bath, 2,3,5-trimethylbenzene-1,4-diol (1 g, 6.57 mmol) and tert-butyl acrylate (1.09 mL, 7.42 mmol) were added under stirring. The reaction continued at 70° C. for 90 min, then the mixture was diluted to 100 ml water and extracted with ethyl acetate 3 times. The extracts were washed with water, saturated NaHCO₃, saturated NaCl, and dried (Na₂SO₄). The solvent was removed by a rotary evaporator. The residue was purified by silica gel chromatography to afford the pure solid lactone 3MCQ (0.81 g, 60% yield). To a solution of lactone 3MCQ (1.8 g, 8.73 mmol) in 90 mL 10% aqueous acetonitrile was added dropwise of a solution of NBS (1.63 g, 9.16 mmol) in 18 mL acetonitrile. The reaction mixture was stirred for 1 hour at 25° C. and the solvent was removed by rotary evaporator. The residue was diluted with water and extracted with several portions of ether. The combined ether extracts were washed with water, brine, and dried (used Na₂SO₄). Removal of solvent and crystallization (acetone-hexane) afforded 1.5 g product AMMMQ (80% yield).

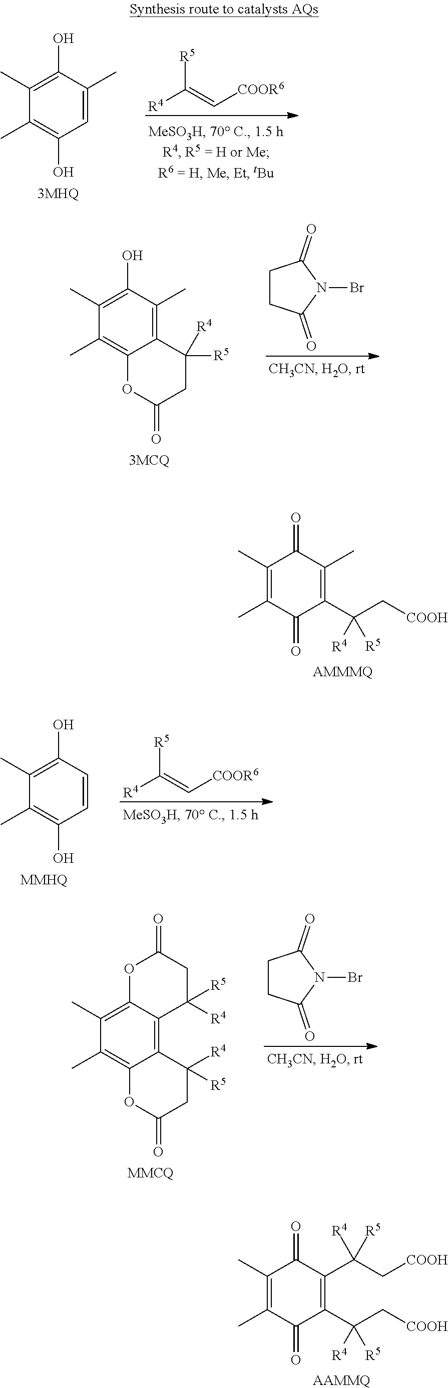

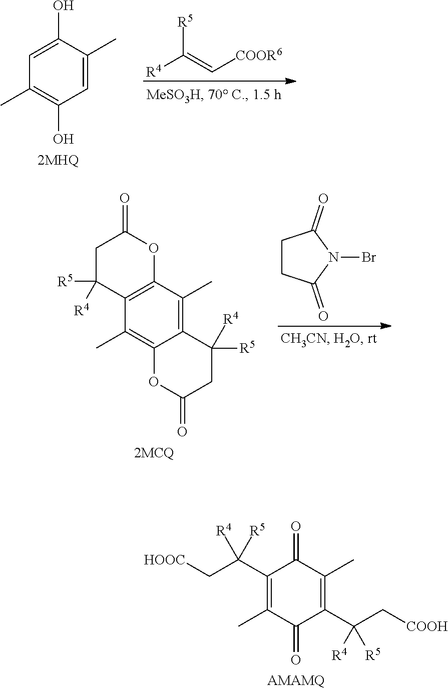

The water-soluble PBFDO micelles were synthesized as follows. To a suspension of catalyst AMMMQ (46.75 mg, 0.21 mmol) in 1.6 ml water was added NaOH (0.42 ml, 0.5 M), and the suspension became a bright yellow solution after stirring for 10 mins. Then, surfactant PDADMAC (100 mg, 0.63 mmol) and monomer HBFDO (40 mg, 0.21 mmol) were added to the reaction mixture and stirred at 100° C. overnight. The catalyst was isolated by filtration, the filtrate PBFDO-water solution was transferred to a dialysis bag, dialyzed in deionized water for 2 days to remove oligomers to obtain PBFDO-water ink. The PBFDO-water ink can be diluted or concentrated by centrifugal dialysis to 1-50 mg/mL for spin-casting, drop-casting, and other thin film processing methods.

The catalyst was recycled as follows. To the isolated AMMMQ/AMMMHQ (45 mg, 0.2 mmol 95% recovery) in 5 mL acetonitrile: H₂O (1:1) was added FeCl₃·6H₂O (215 mg, 0.8 mmol) in 1 mL H₂O solution. The reaction mixture was stirred for 10 min at room temperature and diluted with water, extracted with several portions of ether. The combined ether extracts were washed with water, brine, and dried (Na₂SO₄). Removal of solvent and crystallization (acetone-hexane) yielded 41 mg (92% yield) catalyst AMMMQ.

Using the AQs as described above, the inventors have provided the world's first example of an n-type conducting polymer polymerizing in pure water. According to the method of the present invention, a PBFDO water-based ink having micelle particle size of 120 nm has been manufactured. The PBFDO-water ink with similar excellent solution-processability can be spin-casted and drop-casted in air to obtain thin film conductivity over 50 S/cm.

Although the present invention has been described with reference to various embodiments, those skilled in the art will recognize that changes may be made without departing from the scope of the invention. It is intended that the detailed description be regarded as illustrative and that the appended claims including all the equivalents are intended to define the scope of the invention.

1. A polymer electrolytic capacitor comprising an anode, a dielectric layer and a cathode, wherein said cathode comprises a solution-processed n-type conducting polymer.

2. The polymer electrolytic capacitor according to claim 1, wherein said anode is tantalum (Ta), and said dielectric layer is tantalum oxide (Ta₂O₅).

3. The polymer electrolytic capacitor according to claim 1, wherein said anode is aluminium (Al), and said dielectric layer is tantalum oxide (Al₂O₃).

4. The polymer electrolytic capacitor according to any one of the preceding claims, wherein said solution-processed n-type conducting polymer is poly(benzodifurandione) (PBFDO).

5. The polymer electrolytic capacitor according to any one of the preceding claims, wherein said polymer electrolytic capacitor is in the form of a rectangular SMD chip.

6. The polymer electrolytic capacitor according to any one of claims 1-4, wherein said polymer electrolytic capacitor is in the form of a cylinder.

7. The polymer electrolytic capacitor according to any one of the preceding claims, wherein said polymer electrolytic capacitor is encapsulated.

8. The polymer electrolytic capacitor according to any one of the preceding claims, wherein said solution-processed n-type conducting polymer is manufactured from an ink comprising said solution-processed n-type conducting polymer and a solvent system.

9. The polymer electrolytic capacitor according to claim 8, wherein said solvent system comprises a polar aprotic solvent and/or a polar protic water.

10. The polymer electrolytic capacitor according to claim 9, wherein said polar aprotic solvent is selected from DMF, DMSO, and combinations thereof.

11. The polymer electrolytic capacitor according to claim 9 or 10, wherein said polar protic solvent is selected from water, ethanol, propanol, butanol and combinations thereof.

12. The polymer electrolytic capacitor according to any one of claims 8-11, wherein said ink is applied to said polymer electrolytic capacitor by means of dip-coating.

13. A method for manufacturing a solution-processed n-type conducting polymer said method comprising the steps of:
d) adding a monomer to a solvent system comprising water in the presence of a catalyst, thus providing a reaction solution;
e) allowing said monomer to polymerize in said reaction solution thus obtaining an n-type conducting polymer solution;
f) post-treating said n-type conducting polymer solution thus obtaining a water-soluble n-type conducting polymer.

14. A method according to claim 13, wherein said solvent system consists of water, and wherein said method further comprises a step of:
a′) adding a base to said reaction solution,
wherein step a′) occurs during or immediately after step a).

15. The method according to claim 13, wherein said solvent system further comprises a polar aprotic solvent, and wherein said method further comprises the step of:
g) solvent exchanging such that said polar aprotic solvent is removed.
